(19) United States
(12) Patent Application Publication
(10) Pub. No.: US 2011/0292009 A1
(43) Pub. Date: Dec. 1, 2011

(54) ELECTRONIC DEVICE AND METHOD FOR AUTOMATICALLY ADJUSTING OPENING ANGLE THEREOF

(75) Inventors: TING-KAI WANG, Tu-Cheng (TW); BIN LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/889,536

(22) Filed: Sep. 24, 2010

(30) Foreign Application Priority Data
Jun. 1, 2010 (CN) 201010188636.5

(51) Int. Cl. G09G 5/00; H05K 7/00; G06K 9/46

(52) U.S. Cl. 345/207; 382/195; 361/679.01

(57) ABSTRACT

An electronic device includes a base, a display pivotably connecting to the base, a detecting unit, a processing unit, and a driving unit. The detecting unit is for detecting a positional relationship between the display and a user in front of the display. The processing unit is for generating an adjusting signal according to the positional relationship. The driving unit is for adjusting an opening angle defined between the display and the base according to the adjusting signal.

### BACKGROUND

1. Technical Field

The present disclosure relates to electronic devices, and particularly to an electronic device with a method for automatically adjusting an opening angle.

2. Description of Related Art

An electronic device, such as a notebook computer, usually includes a base and a display pivotably connecting to the base. When the notebook computer is in an open state, an opening angle is defined between the base and the display. However, it is inconvenience that users have to adjust the opening angle by manual operations.

Therefore, there is room for improvement in the art.

### BRIEF DESCRIPTION OF THE DRAWINGS

The components of the drawings are not necessarily drawn to scale, the emphasis instead being placed upon clearly illustrating the principles of the embodiment of an electronic device with a method for automatically adjusting an opening angle. Moreover, in the drawings, like reference numerals designate corresponding parts throughout the views.

FIG. 1 is an isometric, schematic view of an electronic device according to an exemplary embodiment.

FIG. 2 is a functional block diagram of the electronic device of FIG. 1.

FIG. 3 is a partially exploded view of the electronic device of FIG. 1.

FIG. 4 is an isometric, schematic view of an electronic device according to another exemplary embodiment.

FIG. 5 is a flowchart of a method for automatically adjusting an opening angle of an electronic device according to an exemplary embodiment.

FIG. 6 is a flowchart of a method for automatically adjusting an opening angle of an electronic device according to another exemplary embodiment.

### DETAILED DESCRIPTION

Embodiments of the present disclosure will now be described in detail with reference to the drawings.

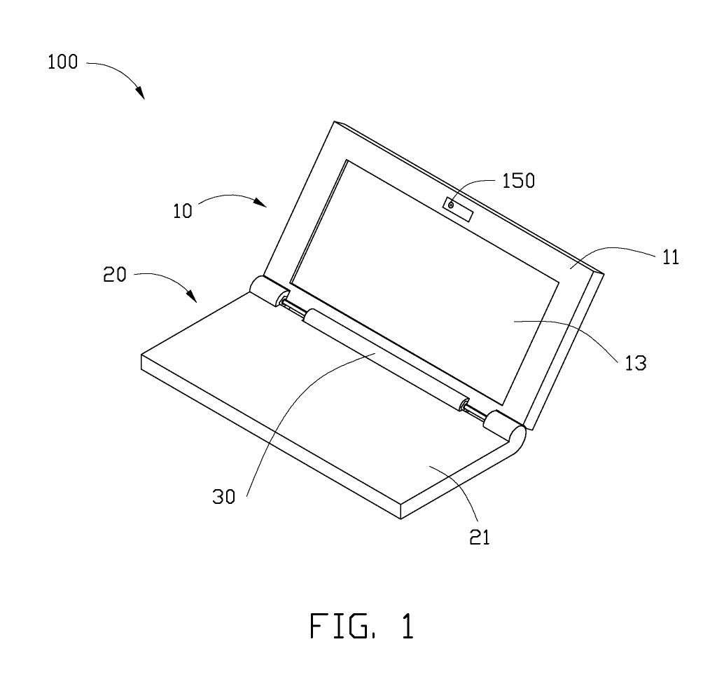

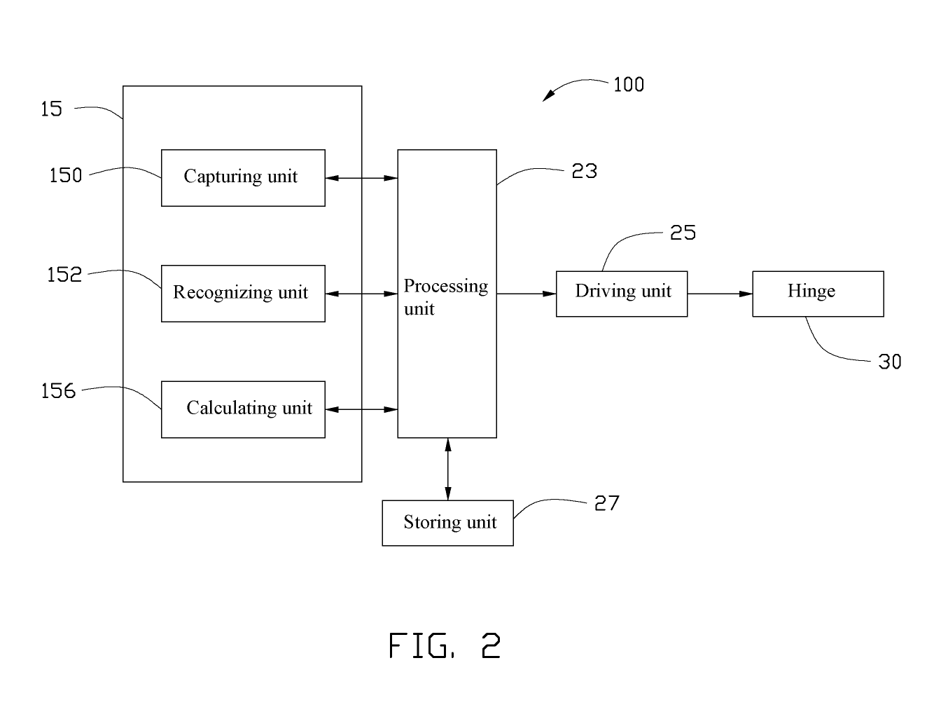

Referring to FIGS. 1 and 2, an electronic device 100 according to an exemplary embodiment is illustrated. In this embodiment, the electronic device 100 is a notebook computer. The electronic device 100 includes a display 10, a base 20, and a hinge 30 for pivotably connecting the display 10 to the base 20.

The display 10 includes a cover 11, a screen 13, and a detecting module 15. The cover 11 is pivotably connected to the base 20 by the hinge 30, thus the cover 11 can rotate with respect to the base 20 to open or be closed. The screen 13 is set on the inside of the cover 11. When the electronic device 100 is in a closed state, the screen 13 covers the base 20.

The detecting module 15 is used for detecting whether a user is in front of the display 10, and further for detecting a positional relationship between the display 10 and the user when the user is in front of the display 10. In this embodiment, the position relationship is a distance between the screen 13 and a face of the user. In other embodiments, the detection module 15 detects the face using a skin color model in YCbCr space or a face template matching technology.

The electronic device 100 can display a menu item for activating the detecting module 15. The electronic device 100 can also set a key for activating the detecting module 15. For example, when the electronic device 100 is in an open state, and the base 20 of the electronic device 100 is activated, the user can activate the detecting module 15 by selecting the menu item or pressing the key. The detecting module 15 includes a capturing unit 150, a recognizing unit 152, and a calculating unit 156.

The capturing unit 150 is used for capturing an image within a predetermined field of view, and the image is located in front of the screen 13 in that field of view. In this embodiment, the capturing unit 150 is a camera installed on the cover 11 beside the screen 13.

The recognizing unit 152 is used for judging whether a human exists within the image, and for further determining a face in the image if it is judged that a human exists within the image.

The calculating unit 156 is used for calculating an area of the face of the image, and further for generating a distance between the screen 13 and the face of the user accordingly. As the capturing unit 150 captures images within the predetermined field of view, all the captured images have a specified distance. Within the predetermined field of view, the farther the distance between the screen 13 and the face of the user is, the smaller the area of the image that the face takes up on the image. The distance between the screen 13 and the face of the user is in proportion to the area that the face takes up on the image. When the calculating unit 156 calculates the area of the face of the image, the distance relative to that face area can be calculated according to proportional differences generated by empirical data.

In this embodiment, the recognizing unit 152 and the calculating unit 156 are preprogrammed into the base 20.

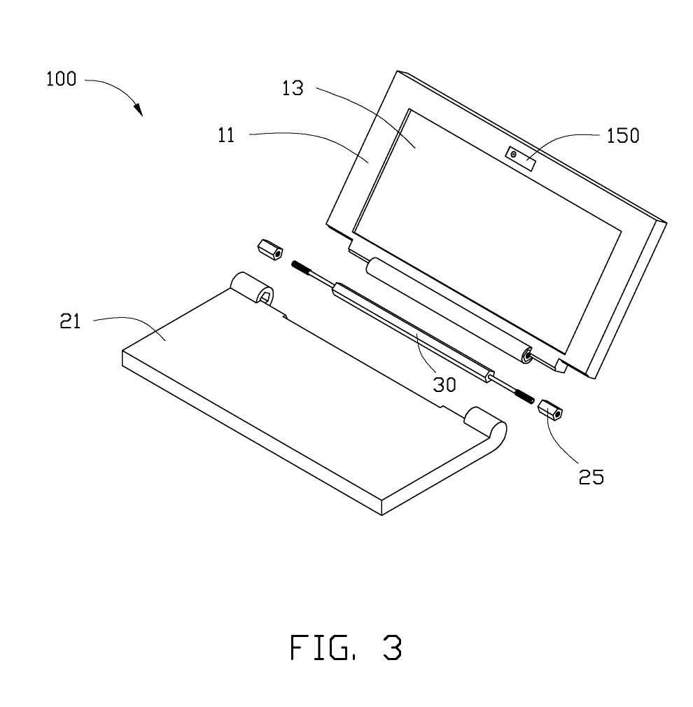

Referring to FIGS. 2 and 3, the base 20 includes a housing 21, a processing unit 23, a driving unit 25, and a storing unit 27. The hinge 30 is rotatable connected with the housing 21. The processing unit 23, the driving unit 25, and the storing unit 27 are received in the housing 21.

The processing unit 23 is used for receiving the distance, determining whether the distance is equal to a predetermined distance which is stored in the storing unit 27, and further for generating an adjusting signal when the distance is not equal to a predetermined distance. The storing unit 27 further stores the proportional differences.

The driving unit 25 is used for receiving the adjusting signal, and further for adjusting an opening angle defined between the display 10 and the base 20 accordingly. Thus, the distance between the screen 13 and the face of the user can keep the predetermined distance. In this embodiment, the driving unit 25 includes two motors. The hinge 30 is set on the cover 11. Two opposite ends of the hinge 30 are received in the housing 21. The two motors are received in the housing and are set on opposite ends of the hinge 30. The two motors are coaxial with the hinge 30 to drive the hinge 30 to rotate. The two motors are electrically connected to the processing unit 23 for receiving the adjusting signal. Thus, the two motors drive the hinge 30 to rotate according to the adjusting signal.

As discussed above, when the electronic device 100 is in the open state, the detecting unit 15 can detect a distance between the screen 13 and the face of the user, and the processing unit 23 generates an adjusting signal according to the distance. The opening angle defined between the display 10 and the base 20 is adjusted by the driving unit 25 according to the adjusting signal. Thus, the distance between the screen 13 and the face of the user can always keep the predetermined distance which is suitable for the user looking at the display 10.

In this embodiment, the driving unit 25 has a range. When the opening angle is out of the range, the processing unit 23 will not activate the driving unit 25 to adjust. The range is about 50˜135 degrees, and is stored in the storing unit 27.

In this embodiment, the storing unit 27 can be embedded into the processing unit 23.

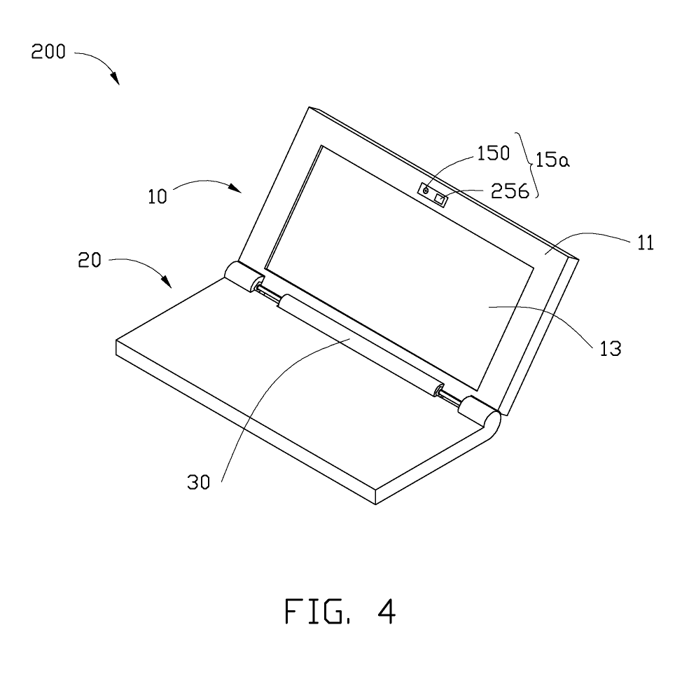

Referring to FIG. 4, another electronic device 200 according to another exemplary embodiment is illustrated. The difference between the two electronic devices 100 and 200 is described as follows. In the electronic device 200, the position relationship is not the distance between the screen 13 of the display 10 and the face of a user, but the distance between the screen 13 of the display 10 and a body of the user. The capturing unit 150 can capture an image with any field of view, and the image is located in front of the screen 13 in that field of view. The calculating unit 256 of the detecting unit 15a is an infrared displacement sensor arranged on the cover 11 beside the screen 13. When the recognizing unit 152 determines a face portion within the image, the recognizing unit 152 judges that there is a user in front of the display 10, and the calculating unit 256 calculates a distance between the display 10 and the body of the user.

In other embodiments, the calculating unit 256 can be a sonar probe or a distance laser sensor which is embedded into a housing of the capturing unit 150.

In other embodiments, the capturing unit 150 and the recognizing unit 152 can be omitted, and whether a human exists within the image is determined by a user.

The electronic device 200 has the similar advantage of the electronic device 100.

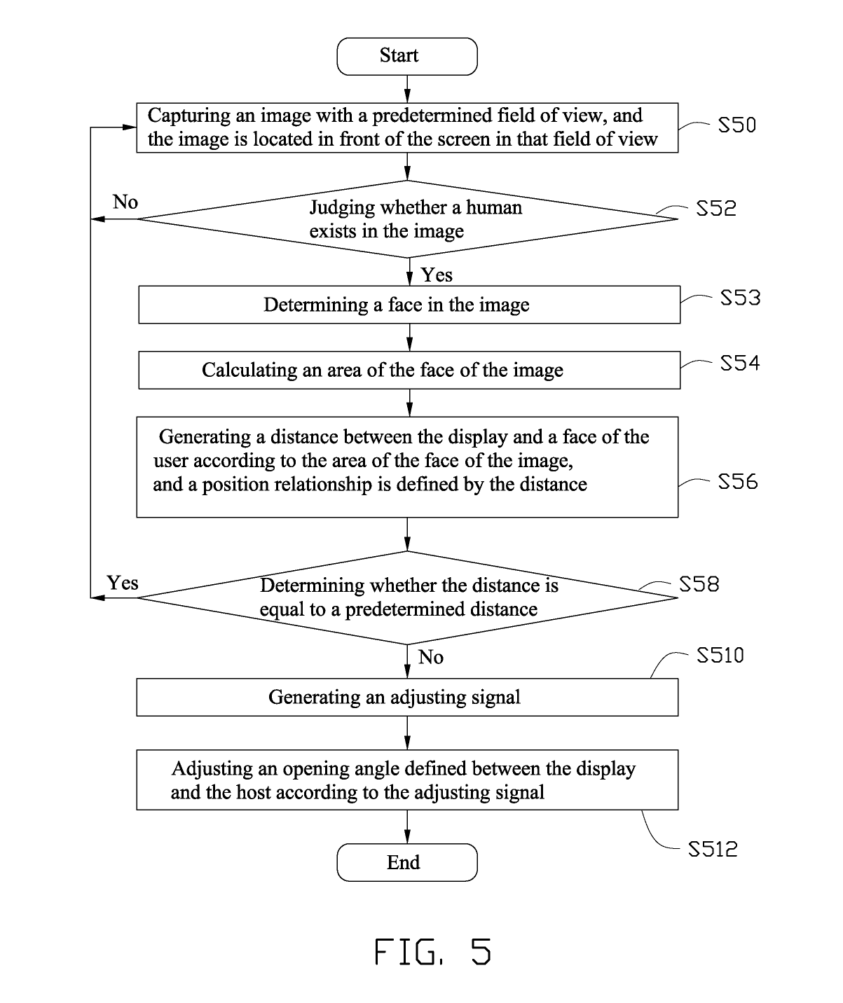

Referring to FIG. 5, a method for automatically adjusting an opening angle of the electronic device 100 is illustrated. The adjusting method shown includes the following steps.

In step S50, capturing an image with a predetermined field of view, and the image is located in front of the screen 13 in that field of view. This step is performed by the capturing unit 150.

In step S52, judging whether a human exists within the image.

In step S53, determining a face in the image if it is judged that a human exists within the image. If it is judged that the image does not include a human face, returning step S50. Steps S52 and S53 are performed by the recognizing unit 152.

In step S54, calculating an area of the face of the image.

In step S56, generating a distance between the display 10 and a face of the user according to the area of the face of the image, and a position relationship is defined by the distance. Steps S54 and S56 are performed by the calculating unit 156.

In step S58, determining whether the distance is equal to a predetermined distance.

In step S510, generating an adjusting signal if it is determined that the distance is not equal to the predetermined distance. If it is determined that the distance is equal to the predetermined distance, returning to step S50. Steps S52 and S53 are performed by the processing unit 23.

In step S512, adjusting an opening angle defined between the display 10 and the base 20 according to the adjusting signal. This step is performed by the driving unit 25.

Finally returning to step S50, a new cycle is started. Thus, the distance between the display 10 and the face of the use can always keep as the predetermined distance which is suitable for the user looking at the display 10.

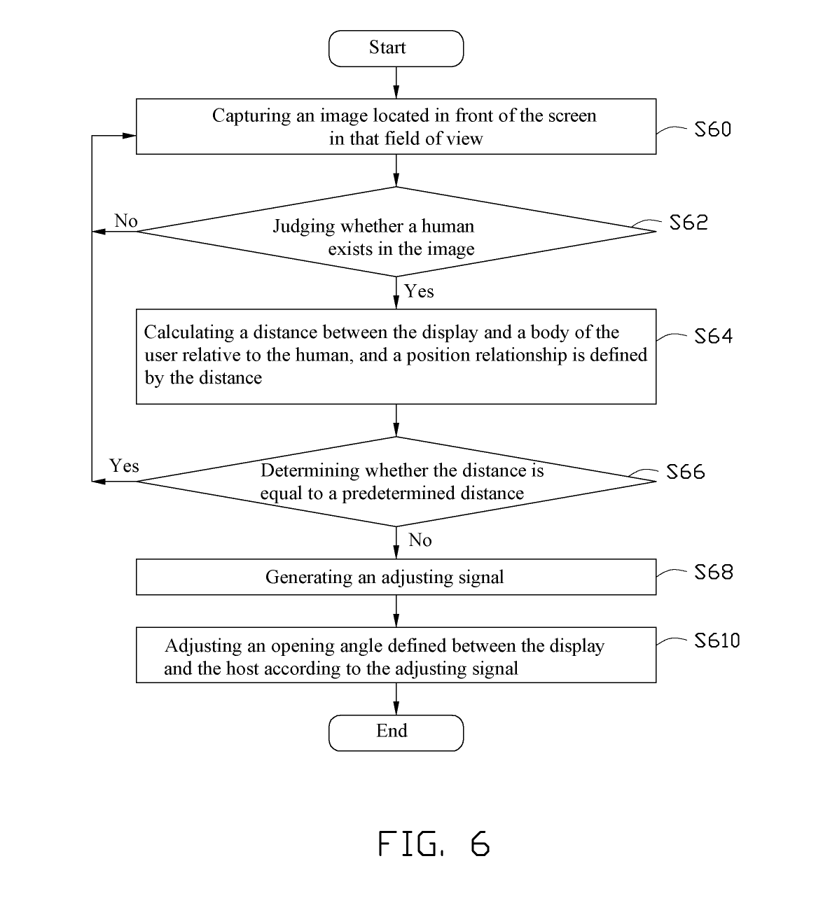

Referring to FIG. 6, another method for automatically adjusting an opening angle of the electronic device 200 is illustrated. The adjusting method shown includes the following steps.

In step S60, capturing an image located in front of the screen 13 in that field of view. This step is performed by the capturing unit 150.

In step S62, judging whether a human exists within the image. This step is performed by the recognizing unit 152.

In step S64, if it is judged that a human exists within the image, calculating a distance between the display 10 and a body of a user relative to the human face, and a position relationship is defined by the distance. This step is performed by the calculating unit 256. If it is judged that the image does not include a human face, returning to step S60.

In step S66, determining whether the distance is equal to a predetermined distance.

In step S68, generating an adjusting signal if it is determined that the distance is not equal to the predetermined distance. If it is determined that the distance is equal to the predetermined distance, returning to step S60. Steps S66 and S68 are performed by the processing unit 23.

In step S610, adjusting an opening angle defined between the display 10 and the base 20 according to the adjusting signal. This step is performed by the driving unit 25.

Finally returning to step S60, a new cycle is started. Thus, the distance between the display 10 and the use can always keep as the predetermined distance which is suitable for the user looking at the display 10.

While various exemplary and preferred embodiments have been described, it is to be understood that the disclosure is not limited thereto. To the contrary, various modifications and similar arrangements (as would be apparent to those skilled in the art) are intended to also be covered. Therefore, the scope of the appended claims should be accorded the broadest interpretation to encompass all such modifications and similar arrangements.

What is claimed is:

1. An electronic device, comprising:
a base;
a display pivotably connected to the base;
a detecting unit for detecting a positional relationship between the display and a user in front of the display;
a processing unit for generating an adjusting signal according to the positional relationship; and
a driving unit for adjusting an opening angle defined between the display and the base according to the adjusting signal.

2. The electronic device of claim 1, wherein the detecting unit is for automatically detecting whether a user is in front of the display, and further for generating the positional relationship between the display and the user if it is determined that the user is in front of the display.

3. The electronic device of claim 1, wherein the detecting unit generates a distance as the positional relationship when it is determined that the user is in front of the display, the distance is defined between the display and a face of the user.

4. The electronic device of claim 3, wherein the detecting unit comprises:
a capturing unit for capturing an image with a predetermined field of view, and the image being located in front of the screen in that field of view;
a recognizing unit for judging whether a human exists within the image, and further for determining a face in the image if it is judged that a human exists in the image; and
a calculating unit for calculating an area of the face of the image, and further for generating the distance accordingly.

5. The electronic device of claim 4, wherein the calculating unit comprises proportional differences defined by different distances and different areas which are in proportion to the corresponding distances, the calculating unit is able to generate a distance by looking up the proportional differences according to an area.

6. The electronic device of claim 3, wherein the processing unit determines whether the distance is equal to a predetermined distance predetermined stored in the processing unit, and generates the adjusting signal if it is determined that the distance is not equal to the predetermined distance.

7. The electronic device of claim 1, wherein the detecting unit generates a distance as the positional relationship when it is determined that the user is in front of the display, the distance is defined between the display and a body of the user.

8. The electronic device of claim 7, wherein the detecting unit comprises:
a capturing unit for capturing an image located in front of the screen in that field of view;
a recognizing unit for judging whether a human exists within the image; and
a calculating unit for calculating the distance between the display and the body of the user relative to the human face, if it is judged that a human exists within the image.

9. The electronic device of claim 7, wherein the processing unit determines whether the distance is equal to a predetermined distance predetermined stored in the processing unit, and generates the adjusting signal if it is determined that the distance is not equal to the predetermined distance.

10. The electronic device of claim 9, further comprising a storing unit for storing the predetermined distance.

11. The electronic device of claim 1, further comprising a hinge for pivotably connecting the display to the base, the driving unit comprising a motor coaxially set on the hinge, the motor for driving the hinge to rotate for adjusting the opening angle according to the adjusting signal.

12. An adjusting method for automatically adjusting an opening angle defined between a display and a base of an electronic device, the adjusting method comprising:
detecting a positional relationship between the display and a user in front of the display;
generating an adjusting signal according to the positional relationship; and
adjusting the opening angle according to the adjusting signal.

13. The adjusting method of claim 12, further comprising:
detecting whether a user is in front of the display;
generating the positional relationship between the display and the user if it is determined that the user is in front of the display.

14. The adjusting method of claim 12, wherein the positional relationship is defined by a distance between the display and a face of the user, and the adjusting signal is generated according to the distance.

15. The adjusting method of claim 14, further comprising:
capturing an image with a predetermined field of view, and the image is located in front of the screen in that field of view;
judging whether a human exists within the image, and further for determining a face in the image if it is judged that a human exists within the image; and
calculating an area of the face of the image, and further for generating the distance between the display and the face of the user accordingly.

16. The adjusting method of claim 15, wherein the distance is generated by looking up proportional differences according to the area, the proportional differences are defined by different distances and different areas in proportion to corresponding distances.

17. The adjusting method of claim 14, further comprising
determining whether the distance is equal to a predetermined distance predetermined stored in the electronic device; and
generating the adjusting signal if it is determined that the distance is not equal to the predetermined distance.

18. The adjusting method of claim 12, wherein the positional relationship is defined by a distance between the display and a body of the user, the adjusting signal is generated according to the distance.

19. The adjusting method of claim 18, further comprising:
capturing an image located in front of the screen in that field of view;
judging whether a human exists within the image; and
calculating the distance between the display and the user relative to the human, if it is judged that a human exists within the image.

20. The adjusting method of claim 18, further comprising:
determines whether the distance is equal to a predetermined distance predetermined stored in the electronic device; and
generating the adjusting signal if it is determined that the distance is not equal to the predetermined distance.
